(19) United States
(12) Patent Application Publication
(10) Pub. No.: US 2011/0073935 A1
(43) Pub. Date: Mar. 31, 2011

(54) NONVOLATILE SEMICONDUCTOR MEMORY DEVICE

(76) Inventors: Akiko SEKIHARA, Yokkaichi-Shi (JP); Tesuya Kai, Yokohama-Shi (JP); Masaaki Higuchi, Yokkaichi-Shi (JP); Yoshio Ozawa, Yokohama-Shi (JP)

(21) Appl. No.: 12/887,114

(22) Filed: Sep. 21, 2010

(30) Foreign Application Priority Data
Sep. 25, 2009 (JP) 2009-221297

(51) Int. Cl. H01L 29/792

(52) U.S. Cl. 257/325; 257/E29.309

(57) ABSTRACT

In one embodiment, a non-volatile semiconductor memory device has a semiconductor layer having a pair of source/drain regions formed at a predetermined distance and a channel region between the pair of source/drain regions; a first insulating film formed above the semiconductor layer; a charge accumulating film formed above the first insulating film; a second insulating film formed above the charge accumulating film; and a control gate electrode film formed above the second insulating film. The first insulating film includes a first oxide film, a first silicon nitride film formed above the first oxide film and including Boron, and a second oxide film formed above the first silicon nitride film.

### CROSS-REFERENCE TO RELATED APPLICATION

This application is based upon and claims the benefit of priority from prior Japanese Patent Application No. 2009-221297, filed on Sep. 25, 2009, the entire contents of which are incorporated herein by reference.

### FIELD

Embodiments described herein relate generally to a nonvolatile semiconductor memory device of a MONOS (Metal-Oxide-Nitride-Oxide-Semiconductor) type.

### BACKGROUND

In a nonvolatile semiconductor memory device that accumulates charges at a charge trap level of a charge accumulating film (insulating film), a so-called MONOS type memory, it is strongly required to improve a write/erase characteristic (increase the write/erase speed) and improve reliability (charge retention characteristic and stress tolerance).

For example, in order to improve an erase characteristic, a technology for configuring a tunnel insulating film of a MONOS type memory cell as an ONO film (three-layered structure film of a silicon oxide film, a silicon nitride film, and a silicon oxide film) of a laminated layer, instead of a silicon oxide film of a single layer, is suggested (for example, Japanese Patent Laid-Open No. 2007-184380).

In this suggestion, an ONO film used as a tunnel insulating film has a silicon nitride film. The silicon nitride film has a characteristic of an energy barrier with respect to a hole being low. Injection efficiency of when the hole is injected into a charge accumulating film through a tunnel insulating film is improved by the use of the silicon nitride film having this characteristic. As a result, an erase characteristic of a MONOS type memory cell is improved.

### BRIEF DESCRIPTION OF THE DRAWINGS

FIG. 1 is a diagram showing the trap level density of a silicon nitride film where various impurities are added;

FIG. 2 is a cross-sectional view of a MOS capacitor that is used in an experiment where a result is shown in FIG. 1;

FIG. 3 is a diagram showing a relationship between the additive amount of boron added to a silicon nitride film and the trap level density of the silicon nitride film;

FIG. 4A is a cross-sectional view of a MONOS type memory cell according to a first embodiment;

FIG. 4B is a diagram specifically showing a portion of FIG. 4A;

FIG. 5A is a diagram showing a measured result of a write/erase characteristic of the MONOS type memory cell according to the first embodiment;

FIG. 5B is a diagram showing a measured result of a charge retention characteristic of the MONOS type memory cell according to the first embodiment;

FIG. 6 is a schematic diagram of a portion of a MONOS type memory with a BiCS structure;

FIG. 7 is a schematic diagram of a MONOS type memory cell with a BiCS structure according to a modification of the first embodiment;

FIG. 8A is a cross-sectional view of a MONOS type memory cell according to the first embodiment;

FIG. 8B is a cross-sectional view of a MONOS type memory cell according to a second embodiment;

FIG. 9 is a diagram showing a measured result of a write/erase characteristic of the MONOS type memory cell according to the second embodiment;

FIG. 10 is a schematic diagram of a MONOS type memory cell with a BiCS structure according to a third embodiment;

FIG. 11A is a diagram showing a measured result of a charge retention characteristic after a write/erase cycle of the MONOS type memory cell with the BiCS structure according to the third embodiment is applied;

FIG. 11B is a diagram showing a measured result of a charge retention characteristic after the MONOS type memory cell with the BiCS structure according to the third embodiment is placed at the high temperature for 10 hours;

FIG. 12 is a cross-sectional view of a MONOS type memory cell according to a modification of the third embodiment;

FIG. 13 is a cross-sectional view of a MONOS type memory cell with a laminated structure according to a fourth embodiment;

FIG. 14A is a diagram showing a measured result of a write/erase characteristic of the MONOS type memory cell according to the fourth embodiment;

FIG. 14B is a diagram showing a measured result of a charge retention characteristic of the MONOS type memory cell according to the fourth embodiment;

FIG. 15 is a cross-sectional view of a MONOS type memory cell with a laminated structure according to a first modification of the fourth embodiment.

### DETAILED DESCRIPTION

A non-volatile semiconductor memory device according to an embodiment comprises: a semiconductor layer having a pair of source/drain regions formed at a predetermined distance and a channel region between the pair of source/drain regions; a first insulating film formed above the semiconductor layer; a charge accumulating film formed above the first insulating film; a second insulating film formed above the charge accumulating film; and a control gate electrode film formed above the second insulating film. The first insulating film includes a first oxide film, a first silicon nitride film formed above the first oxide film and including Boron, and a second oxide film formed above the first silicon nitride film.

Before embodiments are described in detail, the process that the present inventors come to devise the embodiments will be described.

A MONOS type memory cell that uses an ONO film (three-layered structure film of silicon oxide film/silicon nitride film/silicon oxide film) with a laminated structure, instead of a silicon oxide film of a single layer, as a tunnel insulating film is known. The silicon nitride film has a characteristic of an energy barrier with respect to a hole being low. Accordingly, if the MONOS type memory cell using the ONO film as the tunnel insulating film is configured, injection efficiency of when the hole is injected into a charge accumulating film through the tunnel insulating film is improved as compared with the MONOS type memory cell using the silicon oxide film of the single layer. As a result, an erase characteristic of the MONOS type memory cell with the above structure using the ONO film is improved as compared with the MONOS type memory cell using the silicon oxide film of the single layer.

However, through the measurements under various conditions, the present inventors discover the following facts. That is, in the MONOS type memory cell using the ONO film as the tunnel insulating film, a charge retention characteristic after the MONOS type memory cell is placed for a long time (10 hours), under a condition of the high temperature (85° C.), is bad, as compared with the MONOS type memory cell using the silicon oxide film of the single layer.

In addition, the present inventors come to think that the reason why a charge retention characteristic of the MONOS type memory cell using the ONO film is bad is that the silicon nitride film of the ONO film may accumulate charges. This is described in detail below.

The silicon nitride film is used as the charge accumulating film of the MONOS type memory cell. As can be seen from this, the silicon nitride film has a characteristic of accumulating charges. Likewise, the silicon nitride film of the ONO film that is used as the tunnel insulating film has a characteristic of accumulating charges. Therefore, in a write state of the memory cell, the charges are accumulated in the silicon nitride film of the ONO film used as the tunnel insulating film as well as the silicon nitride film used as the charge accumulating film. Since the silicon nitride film of the ONO film is the tunnel insulating film, structurally, the silicon nitride film is disposed at the position close to a channel region. For this reason, the charges that are accumulated in the silicon nitride film of the ONO film may be moved to the channel region, due to an influence from the temperature. As a result, the present inventors come to think that, in the MONOS type memory cell using the ONO film as the tunnel insulating film, the charge retention characteristic after the memory cell is placed at the high temperature for a long time becomes bad as compared with the MONOS type memory cell using the silicon oxide film of the single layer as the tunnel insulating film.

Accordingly, the present inventors come to think that a silicon nitride film that is difficult to accumulate charges, that is, a silicon nitride film where the trap level density to trap the charges is small is used in the ONO film, to prevent a charge retention characteristic of the memory cell from being deteriorated due to accumulation of the charges in the silicon nitride film of the ONO film, while maintaining superior hole injection efficiency.

In addition, the present inventors discover that, from an experimental result obtained by performing various experiments, if boron is added to the silicon nitride film, the trap level density of the silicon nitride film can be decreased.

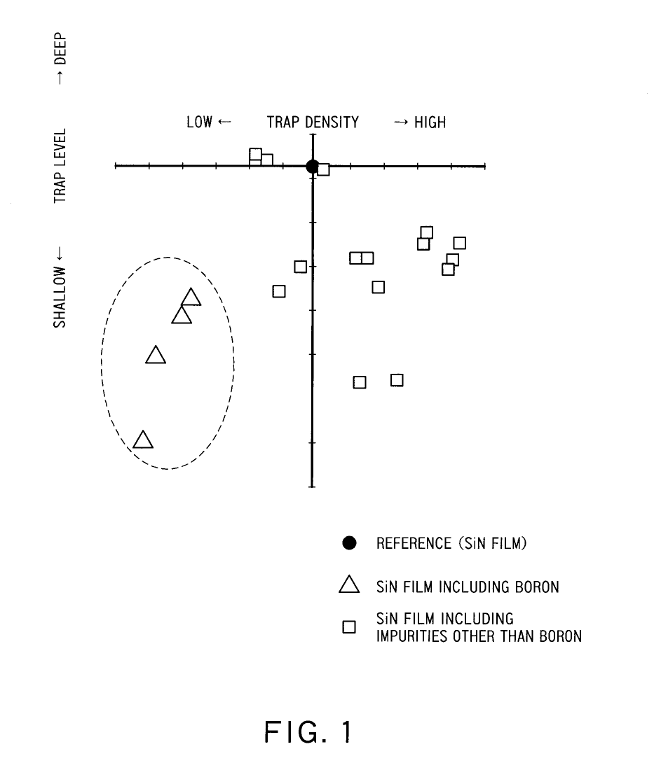

The experimental result that is obtained in the above way is shown in FIG. 1.

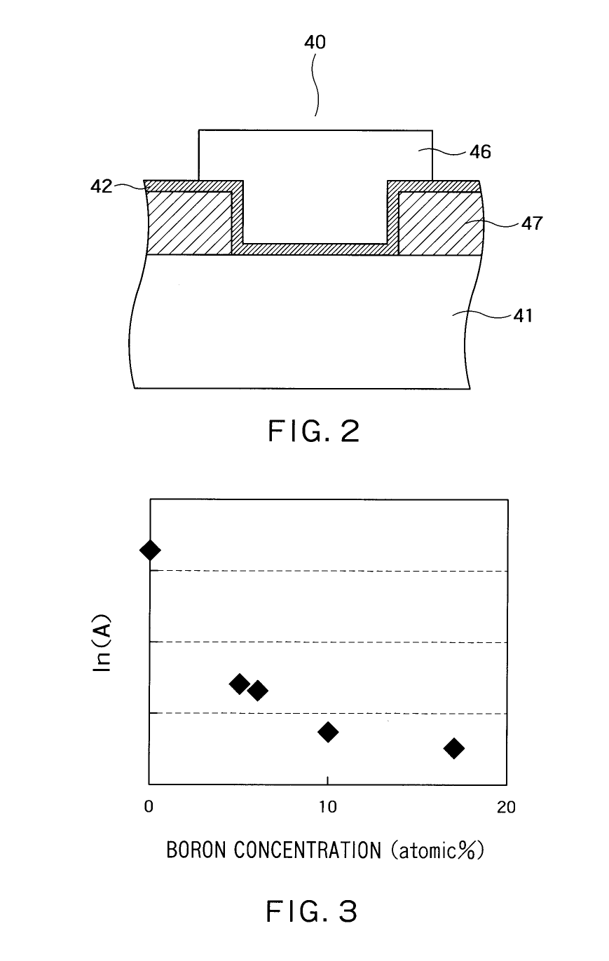

The experimental result shown in FIG. 1 is based on plural MOS capacitors (the thickness of a silicon nitride film is 10 nm and a capacitor size is 100 μm×100 μm) 40 that use a silicon nitride film 42 as a gate insulating film, as shown in FIG. 2. In detail, each of MOS capacitors 40 comprises a silicon oxide film 47 formed on the n-type silicon substrate 41, a silicon nitride film 42 formed to cover the n-type silicon substrate 41 and the silicon oxide film 47, and n-type poly-silicon film 46 formed on the silicon nitride film 42. When these MOS capacitors 40 are manufactured, the silicon nitride film 42 where various impurities are added under the same conditions is used. Specifically, the silicon nitride film 42 is manufactured by thermal CVD (Chemical Vapor Deposition) at the temperature of about 700° C., using dichlorosilane (DCS) and ammonia (NH₃) as raw gas. A temperature characteristic of a leak current of the MOS capacitor 40 that is formed in the above way is measured. The trap level density (specifically, logarithmic value In (A) of the leak current that is correlated with the trap level density) of the silicon nitride film 42 is calculated from the measured result, and the experimental result of FIG. 1 is obtained.

As can be seen from FIG. 1, when impurities other than the boron are added, the trap level density increases, as compared with the silicon nitride film where there is no added impurity. However, when the boron is added, the trap level density decreases, as compared with the silicon nitride film where there is no added impurity.

The present inventors observe an aspect where the trap level density of the silicon nitride film changes by changing the amount of boron added to the silicon nitride film. The observation result is as follows.

The present inventors manufacture the plural MOS capacitors (the thickness of the silicon nitride film is 10 nm and a capacitor size is 100 μm×100 μm) 40 using the silicon nitride film 42 where the boron is added as the gate insulating film, by variously changing the boron concentration of the silicon nitride film 42 (boron concentration of the silicon nitride film: 0 atomic % to 17 atomic %), as shown in FIG. 2. Specifically, the silicon nitride film 42 where the boron is added is manufactured by thermal CVD at the temperature of about 700° C., using dichlorosilane (DCS), ammonia (NH₃), and diborane (B₂H₆) as raw gas.

In each of the plural MOS capacitors 40 that have the silicon nitride film 42 having the various boron concentrations, a temperature characteristic of a leak current is measured, and the trap level density (specifically, logarithmic value In (A) of the leak current that is correlated with the trap level density) of the silicon nitride film 42 is calculated from the measured result. The calculation result is shown in FIG. 3.

As can be seen from FIG. 3, if the boron is added to the silicon nitride film 42, the trap level density of the silicon nitride film 42 decreases when the additive amount of the boron increases. That is, if the born is added to the silicon nitride film, the trap level density of the silicon nitride film can be decreased.

The present inventors estimate the reason why the trap level density decreases when the boron is added to the silicon nitride film as follows.

The silicon nitride film has the high trap level density. The substance of a trap level in the silicon nitride film does not become clear now. However, as for the trap level, an opinion to be a dangling bond is influential.

When based on such an opinion, it is thought that the dangling bond of the silicon nitride film is formed by cutting a structure where a network of constitution elements (silicon and nitrogen) of the film is terminated by impurities of the film, such as hydrogen. In actuality, the fact that a lot of bonds such as Si—H or N—H exist in the silicon nitride film is approved from analysis based on the FT-IR (Fourier Transform Infrared spectroscopy). Further, it is thought that the N—H bond is easy to be cut off, and it is thought that this N—H bond is cut off to form a dangling bond, and the dangling bond becomes the trap level.

If the boron (B) is added to the silicon nitride film, a lot of N—B bonds are formed in the silicon nitride film without forming the N—H bond, because the boron has high responsiveness as compared with the other impurities. Since the N—B bond is a relatively stable bond, it is thought that the N—B bond is difficult to be cut off and it is difficult to form a dangling bond. Accordingly, since the dangling bond is difficult to be generated in the silicon nitride film where the boron is added, it is thought that the trap level density of the silicon nitride film decreases.

That is, as a MONOS type memory according to one embodiment of the present invention, a MONOS type memory in which an ONO film is used as a tunnel insulating film and the boron is added to the silicon nitride film of the ONO film to decrease the trap level density of the film is used. By using this configuration, according to one embodiment of the present invention, a charge retention characteristic of the MONOS type memory can be improved while an erase characteristic is improved.

Next, a first embodiment will be described.

### First Embodiment

The first embodiment relates to a MONOS type memory cell that uses an ONO film including a silicon nitride film where the trap level density is decreased by adding boron, as a tunnel insulating film. By this configuration, a charge retention characteristic of the MONOS type memory cell can be prevented from being deteriorated, while a write/erase characteristic is improved.

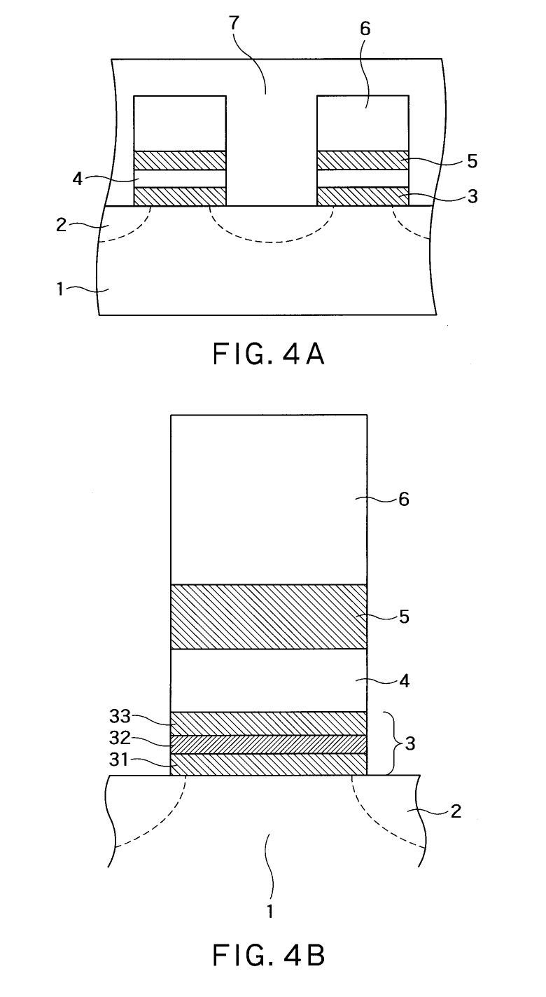

The first embodiment will be described with reference to FIGS. 4A and 4B. FIG. 4A is a cross-sectional view of the MONOS type memory cell according to the first embodiment and FIG. 4B is a partial enlarged view of the same memory cell. That is, in the MONOS type memory cell, plural word lines (not shown in the drawings) and plural bit lines (not shown in the drawings) cross each other at almost a right angle. FIG. 4A is a longitudinal cross-sectional view cut along the bit lines, that is, along a direction of a channel length, in the MONOS type memory cell. Therefore, the plural word lines extend in a direction vertical to a plane of paper of FIG. 4A and the plural bit lines extend in a horizontal direction of FIG. 4A. The MONOS type memory cell according to the first embodiment includes a pair of source/drain regions 2 that are formed at the predetermined distance on a silicon substrate 1 and a channel region that is formed between the pair of source/drain regions. The MONOS type memory cell includes a tunnel insulating film (first insulating film) 3 (for example, thickness of 8 nm), a charge accumulating film (silicon nitride film) 4 (for example, thickness of 5 nm), a block film (second insulating film) (aluminum oxide film) 5 (for example, thickness of 15 nm), and a control gate electrode film (n-type polysilicon film) 6 (for example, thickness of 200 nm), which are laminated on the silicon substrate 1.

Specifically, the memory cell according to the first embodiment uses the ONO film as the tunnel insulating film 3, as shown in FIG. 4B. That is, the ONO film that is used as the tunnel insulating film 3 includes a silicon oxide film (first oxide film) 31 (for example, thickness of 2 nm) that is formed on the silicon substrate 1, a silicon nitride film (first silicon nitride film) 32 (for example, thickness of 2 nm) that is formed on the silicon oxide film 31, and a silicon oxide film (second oxide film) 33 (for example, thickness of 4 nm) that is formed on the silicon nitride film 32, which are laminated from the lower side, in FIG. 4B. The boron is added to the silicon nitride film 32 of the ONO film.

The silicon nitride film 32 where the boron is added is manufactured by thermal CVD (Chemical Vapor Deposition) at the temperature of about 700° C., using DCS, NH₃, and B₂H₆ as raw gas. The boron concentration of the silicon nitride film 32 in this embodiment is about 10 atomic %. However, the boron concentration is not limited to this value and is preferably 1 to 30 atomic %. This reason is as follows. When the boron concentration of the silicon nitride film 32 is less than 1 atomic %, the amount of boron is excessively small and the trap level density of the silicon nitride film 32 cannot be expected to be decreased. Meanwhile, when the boron concentration of the silicon nitride film 32 is equal to or more than 30 atomic %, the amount of boron is excessively large and an insulating property of the silicon nitride film 32 may be deteriorated. Accordingly, when the boron concentration of the silicon nitride film 32 is equal to or more than 30 atomic %, the silicon nitride film 32 is difficult to achieve an original function as the tunnel insulating film 3.

The thermal CVD is advantageous in that the trap level density can be suppressed from increasing due to impurities, because the impurities are small in a manufactured film. As another method for forming the silicon nitride film 32 where the boron is added, an ALD (atomic layer deposition) method that is a kind of CVD method is exemplified. The ALD method deposits a monatomic layer or a monomolecular layer on a substrate surface. The ALD method is superior in control of the boron concentration in a film. As the raw gas of the boron, boron tribromide (BBr3), boron trichloride (BCl₃), boron trifluoride (BF₃), trimethyl borate (B(OCH₃)₃), and boron triethoxide (B(OC₂H₅)₃) as well as B₂H₆ are used.

The tunnel insulating film 3 that is included in the MONOS type memory cell according to this embodiment is not limited to the ONO film with the laminated structure composed of the three films of the silicon oxide film 31, the silicon nitride film 32 where the boron is added, and the silicon oxide film 33. On and below the silicon nitride film 32 where the boron is added, other insulating films that has a higher energy barrier with respect to a hole than the silicon nitride film 32 where the boron is added may be provided. For example, as the insulating films that are provided on and below the silicon nitride film 32 where the boron is added, a silicon oxynitride film (SiON film), an aluminum oxide film or a tantalum oxide film is exemplified. However, when these insulating film materials are used as the insulating films provided on and below the silicon nitride film 32 where the boron is added, it is preferable that the trap level density of these films be sufficiently small. Therefore, it is preferable to sufficiently reduce impurities such as hydrogen or carbon in these films and defects such as the dangling bonds with heat treatment or oxidation treatment.

As the charge accumulating film 4, a film other than the silicon nitride film, for example, another metallic oxide film (for example, hafnium oxide film) can be used.

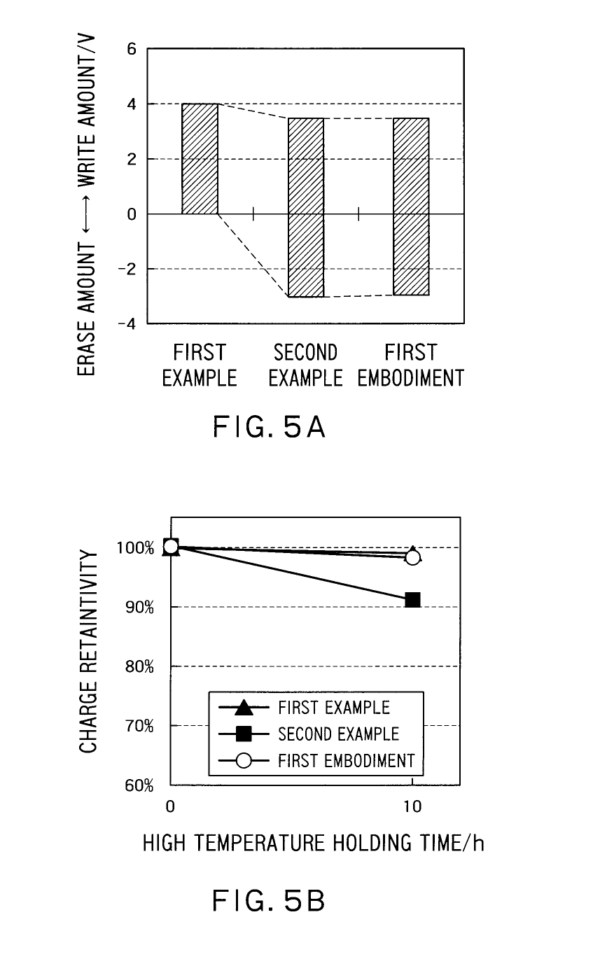

Next, a characteristic of the MONOS type memory cell according to this embodiment will be described with reference to FIGS. 5A and 5B. FIG. 5A shows a write/erase characteristic of each memory cell and FIG. 5B shows a charge retention characteristic after each memory cell is placed at the high temperature (85° C.) for 10 hours.

Specifically, the write/erase characteristic of the memory cell shown in FIG. 5A is obtained as follows. First, a pulse voltage of 18 V is applied to each memory cell for 100 microseconds and a write operation is performed on each memory cell. The write amount at that time is measured by CV measurement. Next, a pulse voltage of −18 V is applied to each memory cell for 100 milliseconds and information that is written in each memory cell is erased. The erase amount at that time is measured by CV measurement. The write amount and the erase amount that are measured in each memory cell are shown in FIG. 5A.

Further, the charge retention characteristic after each memory cell is placed at the high temperature (85° C.) for 10 hours, which is shown in FIG. 5B, is obtained as follows. First, a pulse voltage is applied to each manufactured memory cell such that the predetermined write amount (3 V) is written, and the actual write amount is measured. The write amount at that time is used as the first reference write amount and is set as 100%. Next, each memory cell is placed under an atmosphere of the temperature of 85° C. for 10 hours. Next, the write amount of each memory cell is measured. A ratio (%) of the write amount after the placement of each memory cell for 10 hours with respect to the first reference write amount (100%) of each memory cell that is calculated based on the measured result is shown in FIG. 5B.

The specific configuration of each memory cell that is shown in FIGS. 5A and 5B is as follows. A first example relates to a MONOS type memory cell where a silicon oxide film of a single layer is used as a tunnel insulating film. A second example relates to a MONOS type memory cell where an ONO film is used as the tunnel insulating film and the boron is not added to a silicon nitride film of the ONO film. The first embodiment relates to the MONOS type memory cell where the ONO film is used as the tunnel insulating film and the boron is added to the silicon nitride film of the ONO film.

As can be seen from FIG. 5A, in the second example and the first embodiment where the ONO film is included as the tunnel insulating film, an erase characteristic is improved as compared with the first example where the silicon oxide film of the single layer is included as the tunnel insulating film. That is, if the ONO film is included as the tunnel insulating film, hole injection efficiency is improved and an erase characteristic is improved.

Next, as can be seen from FIG. 5B, in the second example where the ONO film is used as the tunnel insulating film, the charge retention characteristic after each memory cell is placed at the high temperature for 10 hours is bad, as compared with the first example where the silicon oxide film is used as the tunnel insulating film. This reason is as described above. Meanwhile, the charge retention characteristic after each memory cell is placed at the high temperature for 10 hours in the first embodiment where the ONO film is included as the tunnel insulating film and the boron is added to the silicon nitride film of the ONO film is improved as compared with the second example, and is the same as that of the first example.

### Modification of the First Embodiment

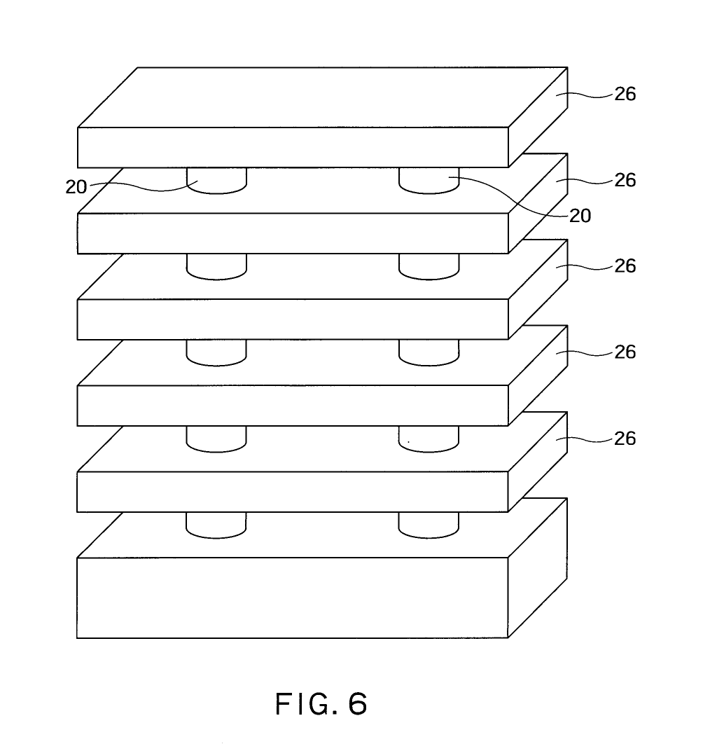

The modification of the first embodiment is to apply the structure of the tunnel insulating film according to the first embodiment to a MONOS type memory with a three-dimensional structure called a BiCS (Bit-Cost-Scalable) structure. A portion of the MONOS type memory with the three-dimensional structure called the BiCS structure is shown in FIG. 6. As shown in FIG. 6, control gate electrode films 26 are laminated and silicon bodies are formed to penetrate the laminated control gate electrode films 26. Memory films 20 (a tunnel insulating film, a charge accumulating film, and a block film) are formed between control gate electrode films 26 and the silicon bodies. In this structure, memory cells are formed at intersections of the control gate electrode films 26 and the silicon bodies and the memory films 20. Even in this modification, similar to the first embodiment, the charge retention characteristic of the MONOS type memory can be prevented from being deteriorated, while the write/erase characteristic thereof is improved.

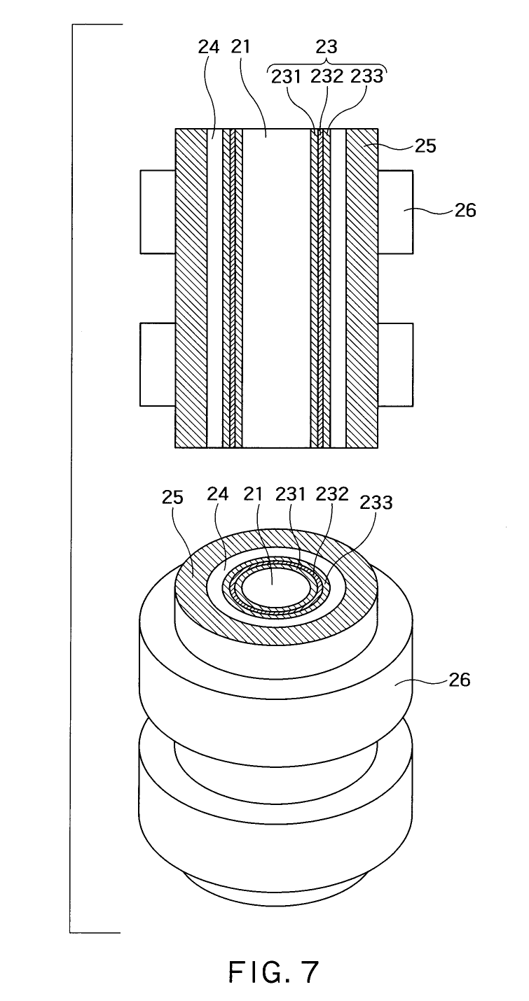

This modification will be described with reference to FIG. 7. FIG. 7 shows two memory cells as a portion of a MONOS type memory with a BiCS structure that is suitable for manufacturing the memory using a BiCS technology. Specifically, an upper stage of FIG. 7 shows a longitudinal section of a memory cell according to this modification. A lower stage of FIG. 7 shows a horizontal section of the memory cell according to this modification. That is, the control gate electrode film 26 is shown in a ring shape in FIG. 7. However, in actuality, the control gate electrode film 26 is configured as a planar film having a large area. In FIG. 7, the two control gate electrode films 26 are laminated in a thickness direction at a predetermined interval. However, in actuality, the control gate electrode films of the number that is more than two are formed in a multilayered state. Therefore, films 21, 23, and 25 having a cylindrical shape and a columnar shape to be described below are formed to have the length in a vertical direction more than the length shown in the drawings. Hereinafter, one memory cell in the MONOS type memory with the BiCS structure will be described. As shown in FIG. 7, the memory cell includes a control gate electrode film (polysilicon film) 26, a block film (second insulating film) 25 that covers an inner surface of a hole formed in the control gate electrode film 26, a charge accumulating film (silicon nitride film) 24 that covers an inner surface of the block film 25, a tunnel insulating film (first insulating film) 23 that covers an inner surface of the charge accumulating film 24, and a silicon body (silicon base) 21 that covers an inner surface of the tunnel insulating film 23. The tunnel insulating film 23 that is composed of the ONO film includes a silicon oxide film (first oxide film) 231 formed at a silicon body side, a silicon oxide film (second oxide film) 233 formed at a charge accumulating film side, and a silicon nitride film (first silicon nitride film) 232 formed between the silicon oxide films 231,233.

Similar to the first embodiment, the boron is added to the silicon nitride film 232 of the tunnel insulating film 23. The boron concentration of the silicon nitride film 232 is preferably 1 to 30 atomic %. This reason is the same as that of the first embodiments.

As a method for forming the silicon nitride film 232 of the tunnel insulating film 23 where the boron is added, an ALD method that uses DCS, NH₃, and B₂H₆ as raw gas and is executed at the temperature of about 550° C. is exemplified. As another method, a thermal CVD method is exemplified.

The tunnel insulating film 23 that is included in the memory cell according to this embodiment is not limited to the ONO film with the laminated structure composed of the three films of the silicon oxide film 231, the silicon nitride film 23 where the boron is added, and the silicon oxide film 233. In order to cause the silicon nitride film 232 where the boron is added to be sandwiched, other insulating films that have a higher energy barrier with respect to a hole than the silicon nitride film 232 where the boron is added may be provided. For example, as the insulating films that sandwich the silicon nitride film 232 where the boron is added, a silicon oxynitride film (SiON film), an aluminum oxide film or a tantalum oxide film is exemplified. However, when these insulating film materials are used as the insulating films sandwiching the silicon nitride film 232 where the boron is added, it is preferable that the trap level density of these films be sufficiently small. Therefore, it is preferable to sufficiently reduce impurities such as hydrogen or carbon in these films and defects such as the dangling bonds with heat treatment or oxidation treatment.

As the charge accumulating film 24, a film other than the silicon nitride film, for example, another metallic oxide film (for example, hafnium oxide film) can be used.

### Second Embodiment

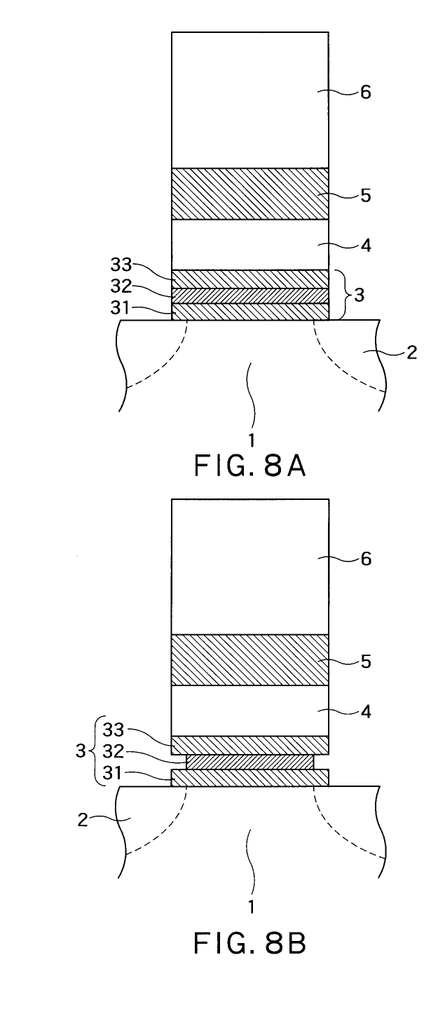

A MONOS type memory cell according to the second embodiment is different from the MONOS type memory cell according to the above-described first embodiment in the structure of the silicon nitride film of the ONO film. Specifically, the difference between the MONOS type memory cell according to the second embodiment and the MONOS type memory cell according to the first embodiment is as follows. As can be seen from a section of the memory cell according to the second embodiment shown in FIG. 8B, sides of the silicon nitride film 32 of the ONO film that is orthogonal to the direction of the channel length retreats to the inner side, as compared with corresponding sides of the charge accumulating film 4. According to this embodiment, a write/erase characteristic of the MONOS type memory can be improved by this structure.

Next, the second embodiment of the present invention will be described with reference to FIG. 8B. FIG. 8B is a cross-sectional view of the memory cell according to the second embodiment. For a comparison with the first embodiment, a cross-sectional view of the memory cell according to the first embodiment of the present invention is shown in FIG. 8A.

As shown in FIG. 8B, similar to the structure of the memory cell according to the first embodiment, the memory cell according to the second embodiment includes a silicon oxide film (first oxide film) 31, a silicon nitride film (first silicon nitride film) 32, and a silicon oxide film (second oxide film) 33, which are laminated on the silicon substrate 1 and constitutes the ONO film 3 corresponding to the tunnel insulating film (first insulating film). Further, the memory cell according to the second embodiment includes a charge accumulating film (silicon nitride film) 4, a block film (second insulating film) (aluminum oxide film) 5, and a control gate electrode film (n-type polysilicon film) 6 that are laminated on the ONO film 3. The silicon nitride film 32 is the silicon nitride film 32 where the boron is added.

However, as described above, different from the memory cell according to the first embodiment, as shown in FIG. 8B, the memory cell according to the second embodiment has a structure in which the pair of sides of the silicon nitride film 32 of the ONO film that is orthogonal to the direction of the channel length retreats to the inner side of 3 nm (10% with respect to the length (30 nm) of the charge accumulating film 4 in the direction of the channel length) from both ends along the direction of the channel length, as compared with the corresponding pair of sides of the charge accumulating film 4. This retreat distance is preferably 1 nm to 5 nm (3% to 16% with respect to the length of the charge accumulating film 4 in the direction of the channel length) and is more preferably 3 nm. This reason is as follows. That is, if the retreat distance is equal to or less than 1 nm, a write/erase characteristic cannot be improved. If the retreat distance is more than 5 nm, the length of the silicon nitride film 32 in the direction of the channel length becomes extremely shorter than the length of the charge accumulating film 4 in the direction of the channel length. As a result, improvement of hole injection efficiency based on the silicon nitride film 32 cannot be realized.

When the memory cell according to the second embodiment having the above structure is formed, the plural memory cells are formed on the silicon substrate 1 and oxidation treatment is performed on sides of each of the memory cells. This oxidizing process is executed under the conditions where the only the sides of the silicon nitride film 32 (silicon nitride film 32 of the ONO film 3) where the boron is added are oxidized and the sides of the silicon nitride film 4 (silicon nitride film 4 corresponding to the charge accumulating film) where the boron is not added are not oxidized, for example, the conditions of an oxygen atmosphere, 1000° C., and 30 sec.

As the charge accumulating film 4, a film other than the silicon nitride film, for example, another metallic oxide film (for example, hafnium oxide film) can be used. In this case, an oxidation method and an oxidation condition according to a used material are used.

The memory cell according to the second embodiment that has the above structure can be obtained by using another method. For example, using the method described in the first embodiment, the plural memory cells may be formed on the silicon substrate, the portions between the adjacent memory cells may be buried with an insulating film having a high hygroscopic property, such as a TEOS (TetraEthOxySilane) oxide film, to cover the sides that is to orthogonal to the direction of the channel length of each memory cell, and high-temperature treatment may be performed. In this way, only the sides of the boron added silicon nitride film 32 of the ONO film 3 that contacts the insulating film having the high hygroscopic property and is easily oxidized are oxidized.

The concentration of the boron that is included in the silicon nitride film 32 in the second embodiment is 10 atomic %. However, the concentration of the boron is not limited to this value and is preferably in a range of 1 to 30 atomic %. Since the reason why the concentration of the boron is limited to the concentration of the above range is the same as that described in the first embodiment, the description thereof will not be repeated herein.

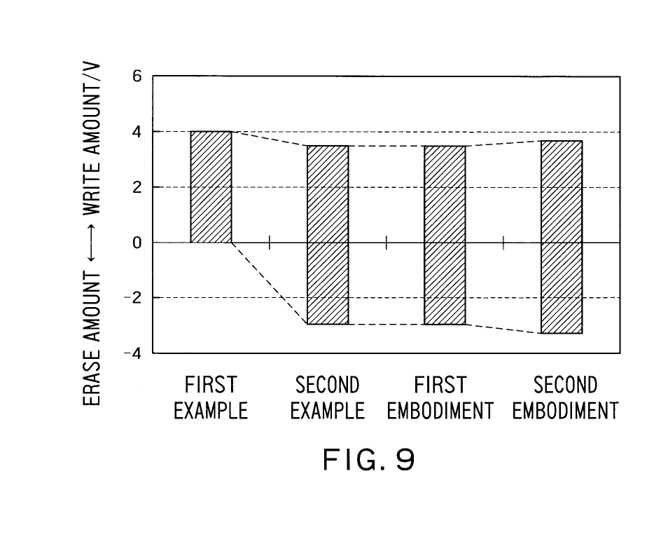

Next, a characteristic of the memory cell according to this embodiment will be described with reference to FIG. 9. FIG. 9 shows a write/erase characteristic of each memory cell. Specifically, the write/erase characteristic of FIG. 9 is obtained using the same measuring method and the same measurement conditions as those described in the first embodiment. Therefore, the detailed description of the measurement method and the measurement conditions will not be repeated herein.

The specific configuration of each memory cell shown in FIG. 9 is as follows. A first example relates to a MONOS type memory cell where a silicon oxide film of a single layer is included as a tunnel insulating film. A second example relates to a MONOS type memory cell where an ONO film is included as the tunnel insulating film and the boron is not added to the silicon nitride film of the ONO film. The first embodiment relates to the MONOS type memory cell where the ONO film is included as the tunnel insulating film and the boron is added to the silicon nitride film of the ONO film. The second embodiment relates to the MONOS type memory cell where the ONO film is included as the tunnel insulating film, the boron is added to the silicon nitride film of the ONO film, and the sides of the silicon nitride film that is orthogonal to the direction of the channel length retreats to the inner side of 3 nm as compared with the corresponding sides of the charge accumulating film.

As can be seen from FIG. 9, in the second embodiment, both the write characteristic and the erase characteristic are improved as compared with the first and second examples and the first embodiment. That is, the write/erase characteristic of the MONOS type memory can be improved by using the structure shown in FIG. 8B.

The present inventors think the reason why the write/erase characteristic of the MONOS type memory is improved when the structure shown in FIG. 8B is used as follows. In the memory cell according to the first embodiment shown in FIG. 8A, the sides of the silicon nitride film 32 of the ONO film (tunnel insulating film) 3 are damaged by etching, which is executed when each memory cell is formed. If the damaged sides of the silicon nitride film 32 are oxidized and removed, the structure shown in FIG. 8B is obtained. In addition, charges or holes are injected into the charge accumulating film 4 through only the silicon nitride film 32 that remains at the central portion of the memory cell, is not damaged, and has a superior film quality. For this reason, the write/erase operation of the memory can be performed with high efficiency. Accordingly, the write/erase characteristic can be improved.

In this case, the MONOS type memory cell where the pair of sides of the silicon nitride film 32 of the ONO film 3 that is orthogonal to the direction of the channel length retreat to the inner side, as compared with the corresponding pair of sides of the charge accumulating film 4 is described, but this embodiment is not limited thereto. For example, the MONOS type memory cell may be a MONOS type memory cell where one side of the pair of sides of the silicon nitride film 32 of the ONO film 3 that is orthogonal to the direction of the channel length retreats to the inner side by the predetermined retreat distance, along the direction of the channel length, as compared with corresponding one side of the charge accumulating film 4.

### Third Embodiment

Before third embodiment is described in detail, the process that the present inventors come to devise the third embodiment will be described.

In general, the MONOS type memory cell with the BiCS stricture has a problem in that the charge retention characteristic is greatly deteriorated due to the stress generated by repeating the write/erase cycle and applied to the memory cell, as compared with the MONOS type memory cell with the laminated structure.

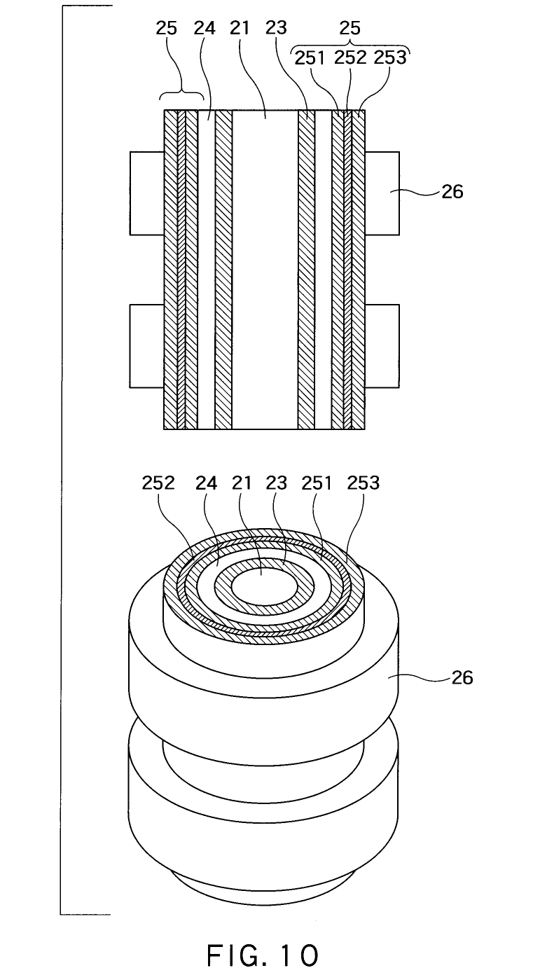

Accordingly, the present inventors adopt the ONO film as the block film 25 of the memory cell with the BiCS structure as shown in FIG. 10. Thereby, the deterioration of the charge retention characteristic after the repetition of the write/erase cycle can be prevented. That is, instead of the oxide film of the single layer, the ONO film that is composed of the three films is used as the block film 25. In this way, flowing of back tunnel electrons into the memory cell (the charge accumulating film 24 and the tunnel insulating film 23) from the control gate electrode film 26 that becomes the reason of the stress applied to the memory cell by repeating the write/erase cycle can be blocked. Accordingly, the deterioration of the charge accumulating film 24 or the tunnel insulating film 23 in the memory cell that is generated due to the inflow of the back tunnel electrons can be prevented.

The present inventors perform the measurements under the various conditions on their own, to confirm whether the memory cell with the BiCS structure satisfies the various conditions imposed as the memory cell. In one of the measurements, the memory cell with the BiCS structure that includes the ONO film as the block film is placed at the high temperature (85° C.) for 10 hours. The present inventors uniquely discover that the charge retention characteristic of the memory cell with the BiCS structure after the placement is deteriorated as compared with the memory cell with the BiCS structure that includes the silicon oxide film of the single layer as the block film.

The present inventors think that the characteristic is deteriorated because the charges are accumulated in the silicon nitride film of the ONO film corresponding to the block film.

That is, as described above, when the write operation is performed, the charges are accumulated in the silicon nitride film of the ONO film that corresponds to the block film. Since the ONO film is structurally located at the position close to the control gate electrode film, the charges that are accumulated in the silicon nitride film of the ONO film are moved to the control gate electrode film due to an influence from the temperature. As a result, the charge retention characteristic after the memory cell with the BiCS structure including the ONO film as the block film is placed at the high temperature for 10 hours is further deteriorated as compared with the memory cell with the BiCS structure including the silicon oxide film of the single layer as the block film.

Therefore, the present inventors add the boron to the silicon nitride film such that the charges are not accumulated in the silicon nitride film of the ONO film corresponding to the block film, that is, the trap level density of the silicon nitride film is decreased, to avoid the characteristic deterioration, similar to the first embodiment.

The MONOS type memory cell according to the third embodiment is characterized by that the ONO film is included as the block film and the boron added silicon nitride film is used as the silicon nitride film of the ONO film as described above.

The third embodiment will be described using the MONOS type memory cell with the BiCS structure shown in FIG. 10.

FIG. 10 shows two memory cells as a portion of a MONOS type memory with the BiCS structure that is suitable for manufacturing the memory using the BiCS technology, similar to FIG. 7. Specifically, an upper stage of FIG. 10 shows a longitudinal section of a memory cell according to this embodiment. A lower stage of FIG. 10 shows a horizontal section of the memory cell according to this embodiment. That is, the control gate electrode film 26 is shown in a ring shape in FIG. 10. However, in actuality, the control gate electrode film is configured as a planar film having a large area. In FIG. 10, the two control gate electrode films 26 are laminated in a thickness direction at a predetermined interval. However, in actuality, the control gate electrode films of the number that is more than two are formed in a multilayered state. Therefore, films 21, 23, and 25 having a cylindrical shape and a columnar shape are formed to have the length in a vertical direction more than the length shown in the drawings. Hereinafter, one memory cell in the MONOS type memory with the BiCS structure will be described.

As shown in FIG. 10, the MONOS type memory cell with the BiCS structure according to the third embodiment includes a control gate electrode film (polysilicon film) 26, a block film (second insulating film) 25 that covers an inner surface of a hole formed in the control gate electrode film 26, a charge accumulating film (silicon nitride film) 24 that covers an inner surface of the block film 25, a tunnel insulating film (first insulating film) 23 that covers an inner surface of the charge accumulating film 24, and a silicon body (silicon base) 21 that covers an inner surface of the tunnel insulating film 23. The block film 25 that is composed of the ONO film includes a silicon oxide film (third oxide film) 251 formed at a charge accumulating film side, a silicon oxide film (fourth oxide film) 253 formed at a control gate electrode film side, and a silicon nitride film (second silicon nitride film) 252 formed between the silicon oxide films 251,253 and including boron.

Specifically, the thickness of the block film 25 is 15 nm, the thickness of the charge accumulating film 24 is 5 nm, the thickness of the tunnel insulating film 23 is 5 nm, and the diameter of the silicon body 21 that has a columnar shape is about 90 nm. For example, the thickness of the silicon oxide film 253 in the block film 25 that is composed of the ONO film is 6 nm, the thickness of the silicon nitride film 252 is 2 nm, and the thickness of the silicon oxide film 251 is 7 nm.

The boron is added to the silicon nitride film 252 of the block film 25. The boron concentration is preferably 1 to 30 atomic %. This reason is the same as that of the first embodiment.

As a method for forming the silicon nitride film 252 of the block film 25 where the boron is added, an ALD method that uses DCS, NH₃, and B₂H₆ as raw gas and is executed at the temperature of about 550° C. is exemplified. As another method, a thermal CVD method is exemplified.

The block film 25 according to this embodiment is not limited to the ONO film with the laminated structure composed of the three films of the silicon oxide film 251, the silicon nitride film 252 where the boron is added, and the silicon oxide film 253. In order to cause the silicon nitride film 252 where the boron is added to be sandwiched, other insulating films that have a higher energy barrier with respect to a hole than the silicon nitride film 252 where the boron is added may be provided. For example, a silicon oxynitride film (SiON film), an aluminum oxide film or a tantalum oxide film is exemplified. However, when these insulating materials are used, it is preferable that the trap level density of these films be sufficiently small. Therefore, it is preferable to sufficiently reduce impurities such as hydrogen or carbon in these films and defects such as the dangling bonds with heat treatment or oxidation treatment.

As the charge accumulating film 24, a film other than the silicon nitride film, for example, another metallic oxide film (for example, hafnium oxide film) can be used.

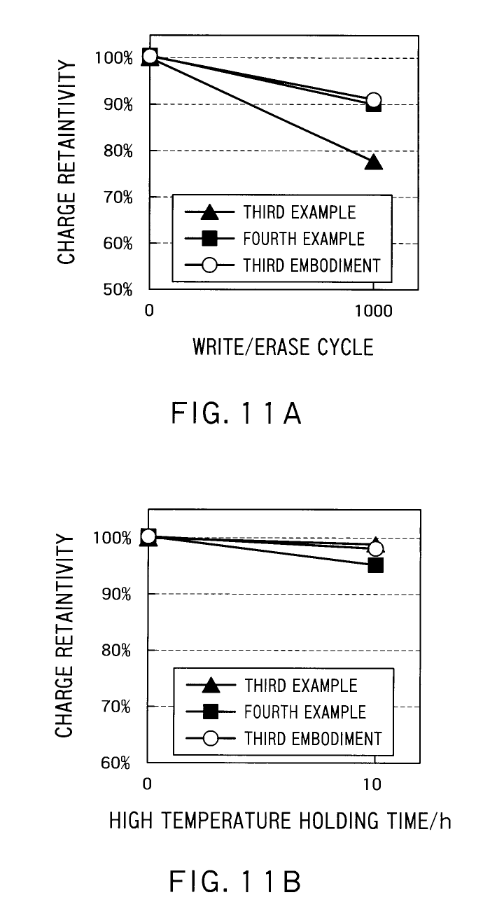

Next, a characteristic of the MONOS type memory cell according to this embodiment will be described with reference to FIGS. 11A and 11B. FIG. 11A shows a charge retention characteristic after repeating a write/erase cycle with respect to the memory cell with a BiCS structure. FIG. 11B shows a charge retention characteristic after the memory cell with the BiCS structure is placed at the high temperature (85° C.) for 10 hours.

The charge retention characteristic after repeating a write/erase cycle of the memory cell shown in FIG. 11A can be obtained as follows. First, a pulse voltage is applied to a manufactured memory cell to become the predetermined write amount (3 V), and the write amount is measured by CV measurement. The write amount at that time is used as the first reference write amount and is set as 100%. Next, a write/erase pulse voltage of the condition that causes the predetermined write amount (3 V) and the predetermined erase amount (−1 V) is repetitively applied to each memory cell (cycle where one write/erase is set as one cycle is repeated 1000 times). Then, the write amount of the memory cell is measured again. A ratio of the write amount at that time to the first write amount (100%) is a value shown in FIG. 11A.

A measuring method of the charge retention characteristic shown in FIG. 11B is the same as the measuring method described in the first embodiment, and measures the charge retention characteristic after each memory cell is placed under an atmosphere of the temperature of 85° C. for 10 hours. Therefore, the detailed description will not be repeated.

The specific configuration of each memory cell that is used in the experiments of FIGS. 11A and 11B is as follows. A third example relates to a MONOS type memory cell with the BiCS structure where a silicon oxide film of a single layer is included as a block film. A fourth example relates to a MONOS type memory cell with the BiCS structure where an ONO film is included as the block film and the boron is not added to a silicon nitride film of the ONO film. The third embodiment relates to the MONOS type memory cell with the BiCS structure where the ONO film is used as the block film and the boron is added to the silicon nitride film of the ONO film.

As can be seen from FIG. 11A, in the fourth example and the third embodiment, a charge retention characteristic after the write/erase cycle is executed is higher as compared with the third example. That is, the charge retention characteristic after the write/erase cycle is executed in the memory cell with the BiCS structure where the ONO film is included as the block film is superior to that of the memory cell with the BiCS structure where the silicon oxide film of the single layer is included as the block film.

As can be seen from FIG. 11B, in the fourth example, the charge retention characteristic after each memory cell is placed at the high temperature for 10 hours is bad, as compared with the third example. This reason is that the charges are accumulated in the silicon nitride film of the ONO film, as described above. However, as shown in FIG. 11B, the charge retention characteristic after each memory cell is placed at the high temperature for 10 hours in the third embodiment is improved as compared with the fourth example. Specifically, the charge retention characteristic after each memory cell is placed at the high temperature for 10 hours in the third embodiment is the same as that of the third example. That is, if the boron is added to the silicon nitride film of the ONO film to decrease the trap level density of the silicon nitride film, the charges can be prevented from being accumulated in the silicon nitride film. Accordingly, the charge retention characteristic after each memory cell is placed at the high temperature for 10 hours in the third embodiment is improved.

The tunnel insulating film according to the third embodiment can be configured as the ONO film that includes the silicon nitride film where the boron is added, similar to the first embodiment.

### Modification of the Third Embodiment

In the third embodiment, the MONOS type memory cell with the BiCS structure is described. However, even in the MONOS type memory cell with the laminated structure according to the first embodiment, the block film can be configured as the ONO film, similar to the third embodiment.

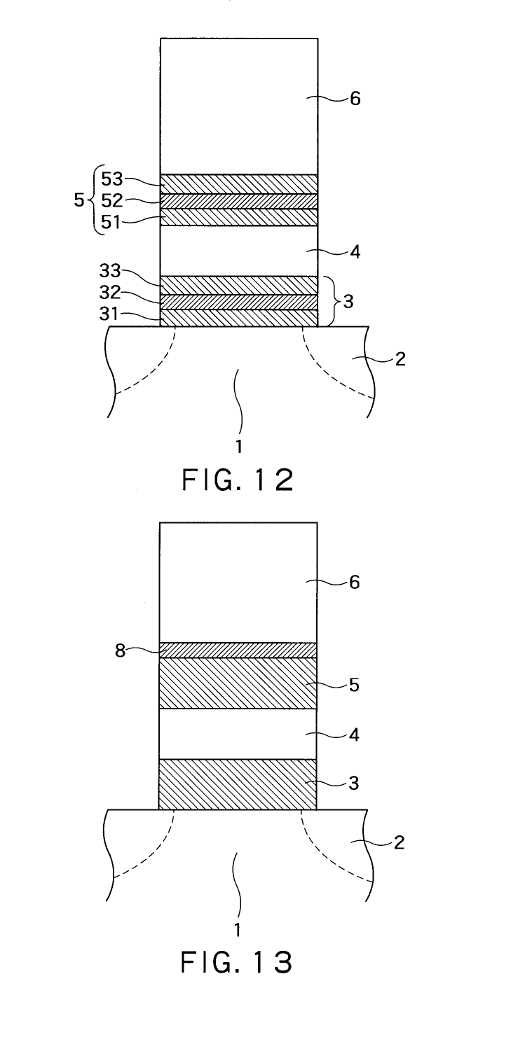

The modification of the third embodiment will be described with reference to FIG. 12. FIG. 12 is a longitudinal cross-sectional view taken along the bit line, that is, along the direction of the channel length, in a plan view of the MONOS type memory cell with the laminated structure. Specifically, similar to the first embodiment, the MONOS type memory cell according to this modification includes a pair of source/drain regions 2 that are formed at the predetermined distance on a silicon substrate 1 and a channel region that is formed between the pair of source/drain regions. Further, the MONOS type memory cell includes a tunnel insulating film (first insulating film) (silicon oxide film) 3, a charge accumulating film (silicon nitride film) 4, a block film (second insulating film) 5, and a control gate electrode film (n-type polysilicon film) 6, which are laminated on the silicon substrate 1. The tunnel insulating film 3 that is composed of the ONO film includes a silicon oxide film (first oxide film) 31, a silicon nitride film (first silicon nitride film) 32 that is formed on the silicon oxide film 31, and a silicon oxide film (second oxide film) 33 that is formed on the silicon nitride film 32. The block film 5 that is composed of the ONO film includes a silicon oxide film (third oxide film) 51, a silicon nitride film (second silicon nitride film) 52 that is formed on the silicon oxide film 51, and a silicon oxide film (fourth oxide film) 53 that is formed on the silicon nitride film 52.

Each of the silicon nitride film 32 of the tunnel insulating film 3 and the silicon nitride film 52 of the block film 5 is a silicon nitride film where the boron is added. The boron concentration is preferably 1 to 30 atomic %. This reason is the same as that of each of the above-described embodiments.

As a method that manufactures the silicon nitride film 32 of the tunnel insulating film 3 where the boron is added and the silicon nitride film 52 of the block film 5 where the boron is added, the method that is described in the above-described embodiments can be used.

Each of the tunnel insulating film 3 and the block film 5 according to this modification is not limited to the ONO film with the laminated structure composed of the three films of the silicon oxide film, the silicon nitride film where the boron is added, and the silicon oxide film. On and below the silicon nitride film where the boron is added, other insulating films that have a higher energy barrier with respect to a hole than the silicon nitride film where the boron is added may be provided. For example, a silicon oxynitride film, an aluminum oxide film or a tantalum oxide film is exemplified. However, when these insulating film materials are used, it is desirable that the trap level density of these films be sufficiently small. Therefore, it is desirable to sufficiently reduce impurities such as hydrogen or carbon in these films and defects such as the dangling bonds with heat treatment or oxidation treatment.

According to the MONOS type memory cell with the laminated structure according to this modification, similar to the third embodiment, the charge retention characteristic after the MONOS type memory cell is placed at the high temperature for 10 hours can be prevented from being deteriorated, while the charge accumulating film or the tunnel insulating film in the MONOS type memory cell can be prevented from being deteriorated due to the inflowing of the back tunnel electrons in the MONOS type memory cell.

### Fourth Embodiment

A MONOS type memory cell according to the fourth embodiment is different from the MONOS type memory cells according to the first to third embodiments in that a cap film is provided between the block film and the control gate electrode film. As the cap film, the silicon nitride film where the boron is added is used. If the MONOS type memory cell is configured to have the above structure, a write/erase characteristic of the MONOS type memory cell, particularly, the erase characteristic can be improved.

The fourth embodiment of the present invention will be described in detail with reference to FIG. 13.

FIG. 13 is a longitudinal cross-sectional view of the memory cell according to the fourth embodiment of the present invention. Specifically, FIG. 13 is a longitudinal cross-sectional view taken along the bit line, that is, along the direction of the channel length, in a plan view of the MONOS type memory cell.

As shown in FIG. 13, similar to the first embodiment, the MONOS type memory cell according to the fourth embodiment includes a pair of source/drain regions 2 that is formed at the predetermined distance on a silicon substrate 1 and a channel region that is formed between the pair of source/drain regions 2. Further, the MONOS type memory cell includes a tunnel insulating film (first insulating film) (silicon oxide film) 3, a charge accumulating film (silicon nitride film) 4, a block film (second insulating film) (aluminum oxide film) 5, and a control gate electrode film (n-type polysilicon film) 6, which are laminated on the silicon substrate 1. Further, the MONOS type memory cell includes a cap film 8 with the thickness of 2 nm (silicon nitride film) that is provided between the block film 5 and the control gate electrode film 6. The cap film 8 is a silicon nitride film where the boron is added. The boron concentration is preferably 1 to 30 atomic %. This reason is the same as that of each of the above-described embodiments.

The method that manufactures the silicon nitride film as the cap film 8, where the boron is added, is described in the above-described embodiments can be used.

As the charge accumulating film 4, a film other than the silicon nitride film, for example, another metallic oxide film (for example, hafnium oxide film) can be used.

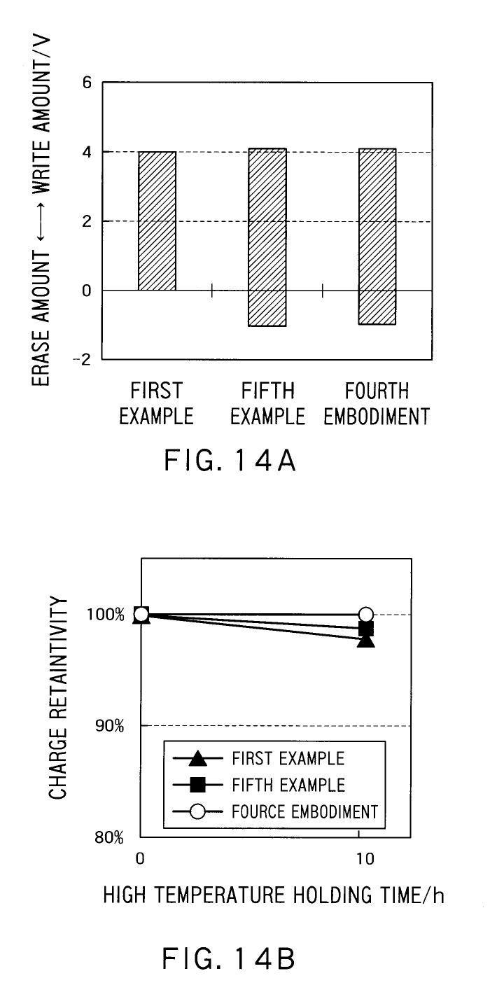

Next, a characteristic of the MONOS type memory cell according to this embodiment will be described with reference to FIGS. 14A and 14B. FIG. 14A shows a write/erase characteristic of the memory cell. FIG. 14B shows the charge retention characteristic after each memory cell is placed at the high temperature for 10 hours, next to the writing. The write/erase characteristic shown in FIG. 14A and the charge retention characteristic after each memory cell is placed at the high temperature for 10 hours shown in FIG. 14B can be obtained by the measuring method described above. Therefore, the detailed description will not be repeated herein.

The specific configuration of each memory cell that is shown in FIGS. 14A and 14B is as follows. A first example relates to a MONOS type memory cell that does not include the cap film. A fifth example relates to a MONOS type memory cell that includes the cap film, and the cap film is a silicon nitride film where the boron is not added. The fourth embodiment relates to the MONOS type memory cell that includes the cap film, and the cap film is a silicon nitride film where the boron of 10 atomic % is added.

As can be seen from FIG. 14A, in the fifth example and the fourth embodiment that include the cap film, the erase characteristic is superior to that of the first example that does not include the cap film.

As can be seen from FIG. 14B, in the memory cell according to the fifth example that includes the silicon nitride film where the boron is not added as the block film, the charge retention characteristic is bad as compared with the first example. Meanwhile, in the memory cell according to the fourth embodiment that includes the silicon nitride film where the boron is added as the cap film, the charge retention characteristic is superior as compared with the first and fifth examples.

The present inventors think the reason as follows. When the accumulated charges are removed from the charge accumulating film included in the MONOS type memory cell, the charges that are accumulated in the charge accumulating film are neutralized and removed by the holes introduced into the charge accumulating film through the tunnel insulating film from the channel region. However, the holes may be neutralized by the back tunnel electrons flowing through the block film from the control gate electrode film. Accordingly, the charges that are accumulated in the charge accumulating film to be originally neutralized with the holes are not smoothly removed. For this reason, an erase characteristic of the memory cell is deteriorated. However, if the cap film is provided between the block film of the memory cell and the control gate electrode film, the back tunnel electrons can be prevented from flowing into the charge accumulating film. As a result, the erase characteristic of the memory cell is improved.

In addition, if the cap film is provided between the block film of the memory cell and the control gate electrode film, the electrons (back tunnel electrons) can be prevented from flowing from the control gate electrode film to the charge accumulating film, and the electrons can be prevented from flowing from the charge accumulating film to the control gate electrode film. Therefore, the charge accumulating film of the MONOS type memory cell can be prevented from being deteriorated.

The reason why the charge retention characteristic after the memory cell is placed at the high temperature for 10 hours is deteriorated when the cap film of the silicon nitride film is provided is the same as the reason described in the other embodiments. That is, since the charges are accumulated in the silicon nitride film corresponding to the cap film and the cap film is disposed at the position close to the control gate electrode film, the charges that are accumulated in the silicon nitride film corresponding to the cap film may be moved to the control gate electrode film. If the cap film is configured as the silicon nitride film where the boron is added, the charges are difficult to be accumulated in the silicon nitride film, similar to the first embodiment. Therefore, the charge retention characteristic after the memory cell is placed at the high temperature for 10 hours is improved.

The silicon nitride film that is used as the cap film in the fourth embodiment can be configured to have the same structure as that of the silicon nitride film of the ONO film used as the tunnel insulating film in the second embodiment. That is, even in the fifth embodiment, if the sides of the silicon nitride film corresponding to the cap film that is orthogonal to the direction of the channel length are oxidized, the corresponding sides of the silicon nitride film corresponding to the cap film that is orthogonal to the direction of the channel length can be configured to retreat to the inner side as compared with the corresponding sides of the control gate electrode film laminated on the silicon nitride film. In this way, similar to the second embodiment, the write/erase characteristic of the memory can be improved. In addition, similar to the second embodiment, the structure of the memory cell is not limited to the structure in which the pair of sides of the silicon nitride film corresponding to the cap film that is orthogonal to the direction of the channel length retreat to the inner side as compared with the corresponding pair of sides of the control gate electrode film laminated on the silicon nitride film. The one side of the pair of sides of the silicon nitride film corresponding to the cap film that is orthogonal to the direction of the channel length may retreat to the inner side, as compared with the corresponding side of the control gate electrode film laminated on the silicon nitride film.

### Modification of the Fourth Embodiment

In the modification of the fourth embodiment, the tunnel insulating film in the fourth embodiment can be configured as the ONO film that includes the silicon nitride film where the boron is added, similar to the first embodiment. If the MONOS type memory cell with the laminated structure is configured to have the above structure, a write/erase characteristic of the MONOS type memory cell, particularly, the erase characteristic can be improved.

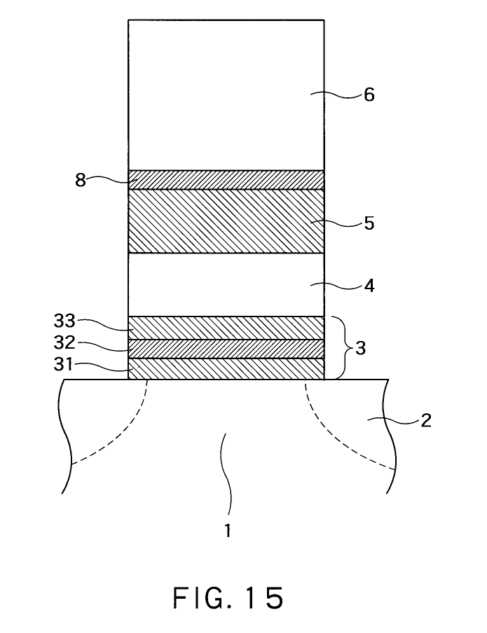

The modification of the fourth embodiment will be described with reference to FIG. 15. FIG. 15 is a longitudinal cross-sectional view taken along the bit line, that is, along the direction of the channel length, in a plan view of the MONOS type memory cell. Specifically, similar to the first embodiment, the MONOS type memory cell according to this modification includes a pair of source/drain regions 2 that are formed at the predetermined distance on a silicon substrate 1 and a channel region that is formed between the pair of source/drain regions 2. Further, the MONOS type memory cell includes a tunnel insulating film (first insulating film) (silicon oxide film) 3, a charge accumulating film (silicon nitride film) 4, a block film (second insulating film) 5, and a control gate electrode film (n-type polysilicon film) 6, which are laminated on the silicon substrate 1. The tunnel insulating film 3 that is composed of the ONO film includes a silicon oxide film (first oxide film) 31, a silicon nitride film (first silicon nitride film) 32 that is formed on the silicon oxide film 31, and a silicon oxide film (second oxide film) 33 that is formed on the silicon nitride film 32. Further, the MONOS type memory cell includes the cap film (silicon nitride film) 8 that is provided between the block film 5 and the control gate electrode film 6.

Each of the silicon nitride film 32 of the tunnel insulating film 3 and the cap film 8 is a silicon nitride film where the boron is added. The boron concentration is preferably 1 to 30 atomic %. This reason is the same as that of each of the above-described embodiments.

A method that manufactures the silicon nitride film 32 of the tunnel insulating film 3 and the silicon nitride film 8 corresponding to the cap film is described in the above-described embodiments can be used.

As another modification, the silicon nitride film where the boron is added as the cap film can be included between the block film and the control gate electrode film, even in the MONOS type memory cell with the BiCS structure according to the modification of the first embodiment and the MONOS type memory cell with the BiCS structure according to the third embodiment.

According to the first to the fourth embodiments and the modifications thereof described above, the erase characteristic and the charge retention characteristic of the MONOS type memory cell can be improved using the silicon nitride film where the boron is added.

In the first to fourth embodiments described above, the examples of the case where the MONOS type memory cell is formed in the silicon substrate and the silicon body are described. However, the substrate where the MONOS type memory cell is formed is not necessarily the silicon substrate, and may be a substrate using other materials (for example, SOI substrate or SiGe substrate). As such, the MONOS type memory cell can be formed on the various semiconductor layers.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A non-volatile semiconductor memory device, comprising:
a semiconductor layer having a pair of source/drain regions formed at a predetermined distance and a channel region between the pair of source/drain regions;
a first insulating film formed above the semiconductor layer;
a charge accumulating film formed above the first insulating film;
a second insulating film formed above the charge accumulating film; and
a control gate electrode film formed above the second insulating film,
wherein the first insulating film includes a first oxide film, a first silicon nitride film formed above the first oxide film and including Boron, and a second oxide film formed above the first silicon nitride film.

2. The non-volatile semiconductor memory device according to claim 1
wherein the boron included in the first silicon nitride film has the concentration of 1 to 30 atomic %.

3. The non-volatile semiconductor memory device according to claim 1,
wherein each of the first oxide film and the second oxide film is any one of a silicon oxide film, a silicon oxynitride film, a tantalum oxide film, and an aluminum oxide film.

4. The non-volatile semiconductor memory device according to claim 1,
wherein the second insulating film comprises a third oxide film formed above the charge accumulating film, a second silicon nitride film formed above the third oxide film and including Boron, and a fourth oxide film formed above the second silicon nitride film.

5. The non-volatile semiconductor memory device according to claim 4,
wherein the boron included in the second silicon nitride film has the concentration of 1 to 30 atomic %.

6. The non-volatile semiconductor memory device according to claim 4,
wherein each of the third oxide film and the forth oxide film is any one of a silicon oxide film, a silicon oxynitride film, a tantalum oxide film, and an aluminum oxide film.

7. The non-volatile semiconductor memory device according to claim 1, further comprising:
a cap film located between the second insulating film and the control gate electrode film,
wherein the cap film is a silicon nitride film including boron.

8. The non-volatile semiconductor memory device according to claim 7,
wherein the boron included in the silicon nitride film as the cap film has the concentration of 1 to 30 atomic %.

9. The non-volatile semiconductor memory device according to claim 1,
wherein at least one side of the pair of sides of the first silicon nitride film, the pair of sides being orthogonal to the direction of a channel length, retreats to the inner side by a predetermined distance along the channel length direction, as compared with corresponding one of sides of the charge accumulating film.

10. A non-volatile semiconductor memory device, comprising:
a control gate electrode film;
a silicon base formed to penetrate the control gate electrode film;
a first insulating film formed at a silicon base side and a second insulating film formed at a control gate electrode film side, the first and the second insulating film being between the control gate electrode film and the silicon base; and
a charge accumulating film formed between the first insulating film and the second insulating film,
wherein the first insulating film has a first oxide film formed at a silicon base side, the first oxide film being between the silicon base and the charge accumulating film, a second oxide film formed at a charge accumulating film side, the second oxide film being between the silicon base and the charge accumulating film, and a first silicon nitride film formed between the first oxide film and the second oxide film and including Boron.

11. The non-volatile semiconductor memory device according to claim 10,
wherein the boron included in the first silicon nitride film has the concentration of 1 to 30 atomic %.

12. The non-volatile semiconductor memory device according to claim 10,
wherein each of the first oxide film and the second oxide film is any one of a silicon oxide film, a silicon oxynitride film, a tantalum oxide film, and an aluminum oxide film.

13. The non-volatile semiconductor memory device according to claim 10,
wherein a plurality of the control gate electrode films are formed in a laminated state at a predetermined interval,
the silicon base is formed to penetrate each of the plurality of the control gate electrode films along a thickness direction of the control gate electrode films, and
each of the first insulating film and the second insulating film is formed integrally between the plurality of the control gate electrode films and the silicon base.

14. The non-volatile semiconductor memory device according to claim 10,
wherein a plurality of holes penetrating the control gate electrode film is formed, and
the first insulating film, the charge accumulating film, the second insulating film, and the silicon base are formed with respect to each of the holes.

15. The non-volatile semiconductor memory device according to claim 10,
wherein the second insulating film has a third oxide film formed at a charge accumulating film side, the third oxide film being between the control gate electrode film and the charge accumulating film, a fourth oxide film formed at a control gate electrode film side, the fourth oxide film being between the control gate electrode film and the charge accumulating film, and second silicon nitride film formed between the third oxide film and the fourth oxide film and including Boron.

16. The non-volatile semiconductor memory device according to claim 15,
wherein the boron included in the second silicon nitride film has the concentration of 1 to 30 atomic %.

17. The non-volatile semiconductor memory device according to claim 15,
wherein each of the third oxide film and the fourth oxide film is any one of a silicon oxide film, a silicon oxynitride film, a tantalum oxide film, and an aluminum oxide film.

18. A non-volatile semiconductor memory device, comprising:
a control gate electrode film;
a silicon base formed to penetrate the control gate electrode film;
a first insulating film formed at a silicon base side and a second insulating formed at a control gate electrode film side, the first and second insulating film being between the control gate electrode film and the silicon base; and
a charge accumulating film formed between the first insulating film and the second insulating film,
wherein the second insulating film is configured to include a silicon nitride film including Boron, and oxide films, one of the oxide films being between the control gate electrode film and the silicon nitride film, other of the oxide films being between the charge accumulating film and the silicon nitride film.

19. The non-volatile semiconductor memory device according to claim 18,
wherein the boron included in the silicon nitride film has the concentration of 1 to 30 atomic %.

20. The non-volatile semiconductor memory device according to claim 18,
wherein each of the oxide films is any one of a silicon oxide film, a silicon oxynitride film, a tantalum oxide film, and an aluminum oxide film.
